(19) United States
(12) Patent Application Publication
(10) Pub. No.: US 2025/0308954 A1
(43) Pub. Date: Oct. 2, 2025

(54) SYSTEMS AND METHODS FOR ALIGNMENT AND PLACEMENT OF ELECTRONIC DEVICES ON CARRIER TAPE

(71) Applicant: KLA Corporation, Milpitas, CA (US)

(72) Inventors: Gabriel Mauricio Probst, Leuven (BE); Wouter Paesen, Pelt (BE); Jimmy Vermeulen, Milpitas, CA (US); Bert Vangilbergen, Milpitas, CA (US); Ye Tan, Milpitas, CA (US); Bart De Mot, Milpitas, CA (US)

(21) Appl. No.: 18/618,159

(22) Filed: Mar. 27, 2024

(51) Int. Cl. H01L 21/67; B25J 15/06; H01L 21/673; H01L 21/68; H01L 21/683; H05K 13/04

(52) U.S. Cl. CPC H01L 21/67132; B25J 15/0616; H01L 21/67333; H01L 21/681; H01L 21/6838; H05K 13/0409

(57) ABSTRACT

The system includes a taping head configured to extract a plurality of devices from a plurality of tray pockets of a component tray and a first camera configured to capture one or more images of the plurality of devices extracted by the taping head. A processor is configured to determine size and orientation information of each of the plurality of devices extracted by the taping head based on the one or more images of the plurality of devices received from the first camera, determine a placement solution of the taping head to position each of the plurality of devices into the plurality of tape pockets of a carrier tape based on the size and orientation information of each of the plurality of devices, and control the taping head to place the plurality of devices into the plurality of tape pockets of the carrier tape according to the placement solution.

### FIELD OF THE DISCLOSURE

This disclosure relates to handling electronic devices and, more particularly, to a placement of electronic devices on a carrier tape.

### BACKGROUND OF THE DISCLOSURE

Evolution of the electronics manufacturing industry is placing greater demands on yield management and, in particular, on metrology and inspection systems. Critical dimensions continue to shrink, yet the industry needs to decrease time for achieving high-yield, high-value production. Minimizing errors reduces throughput time and maximizes the return-on-investment for an electronics manufacturer.

Some high-speed electronics manufacturing systems rely on a carrier tape loaded with electronic devices (e.g., integrated circuits (ICs), chips, etc.), which feeds the electronic devices to the system for assembly onto a printed circuit board (PCB) or other electronic assembly. In particular, the carrier tape includes a plurality of tape pockets which each contain an electronic device. Since the electronic devices are not manufactured within the tape pockets, they must be transferred from another setting (e.g., tray pockets of a separate component tray) into the carrier tape. A placement system can rely on a theoretical model of the size and positions of the electronic devices in the component tray and the dimensions of the tape pockets to place the electronic devices into the tape pockets. However, due to tolerances of the size of the tray pockets, the electronic devices, and the tape pockets, the actual positions of the electronic devices being held by the placement system may differ from the theoretical model due to the tray pocket tolerances and mechanical inaccuracies of the placement system in combination with the tray carrier system, causing the placement system to misplace an electronic device into a pocket of the carrier tape, as the placement system is unaware of such divergences. Misplaced electronic devices may cause jamming of the feed, which requires correction and reduces yield.

Therefore, what is needed is a placement system that can reduce errors when transferring electronic devices to a carrier tape with high speed.

### BRIEF SUMMARY OF THE DISCLOSURE

An embodiment of the present disclosure provides a system comprising a taping head, a first camera, and a processor in electronic communication with the taping head and the first camera. The taping head may be configured to extract a plurality of devices from a plurality of tray pockets of a component tray. The first camera may be configured to capture one or more images of the plurality of devices extracted by the taping head. The processor may be configured to determine size and orientation information of each of the plurality of devices extracted by the taping head based on the one or more images of the plurality of devices received from the first camera. The processor may be further configured to determine a placement solution of the taping head to position each of the plurality of devices into a plurality of tape pockets of a carrier tape based on the size and orientation information of each of the plurality of devices. The placement solution may comprise at least one corrective movement of the taping head and a drop sequence of placing each of the plurality of devices into the plurality of tape pockets of the carrier tape. The processor may be further configured to control the taping head to place the plurality of devices into the plurality of tape pockets of the carrier tape according to the placement solution.

In some embodiments, the system may further comprise a second camera configured to capture one or more images of the plurality of tape pockets of the carrier tape, and the processor may be in electronic communication with the second camera. The processor may be further configured to determine dimension and position information of each of the plurality of tape pockets of the carrier tape based on the one or more images of the plurality of tape pockets of the carrier tape received from the second camera; and determine the solution space and boundaries of the plurality of tape pockets of the carrier tape base on the dimension and position information of each of the plurality of tape pockets.

In some me the corrective movement comprises a translational adjustment and/or a rotational adjustment of the taping head relative to the plurality of tape pockets of the carrier tape.

In some embodiments, the processor may be further configured to determine locations of a center point and four corners of each of the plurality of devices based on the size and orientation information of each of the plurality of devices; compare the locations of the center point and four corners of each of the plurality of devices to a solution space and boundaries of each of the plurality of tape pockets of the carrier tape; and determine the corrective movement of the taping head to position the locations of the center point and four corners of each of the plurality of devices within the solution space and boundaries of each of the plurality of tape pockets of the carrier tape.

In some embodiments, the processor may be further configured to determine a translational adjustment of the corrective movement to adjust an x, y position of the taping head such that the locations of the center point of each of the plurality of devices are within the solution space of each of the plurality of tape pockets of the carrier tape; and determine a rotational adjustment of the corrective movement to adjust an angle along a rotation axis of the taping head such that the locations of the four corners of each of the plurality of devices are within the boundaries of each of the plurality of tape pockets of the carrier tape.

In some embodiments, the plurality of devices may comprise N devices, and the drop sequence may comprise 1 to N drops. The processor may be further configured to: iteratively reduce the number of devices in a drop in the drop sequence when no single corrective movement of the taping head positions the locations of the center point and four corners of each of the plurality of devices within the solution space and boundaries of each of the plurality of tape pockets of the carrier tape; determine a corrective movement of the taping head to position the locations of the center point and four corners of each grouping of the plurality of devices within the solution space and boundaries of each corresponding grouping of the plurality of tape pockets of the carrier tape; define the drop sequence based on the number of groupings of the plurality of devices having a corresponding corrective movement; and control the taping head to place each grouping of the plurality of devices into each corresponding grouping of the plurality of tape pockets of the carrier tape according to the corresponding corrective movement and the drop sequence.

In some embodiments, the taping head comprises a plurality of vacuum pads configured to individually engage each of the plurality of devices based on vacuum pressure from a vacuum source. The processor may be in electronic communication with the vacuum source. The processor may be further configured to control the vacuum source to apply vacuum pressure to the plurality of vacuum pads to extract the plurality of devices from the plurality of tray pockets of the component tray; and control vacuum source to stop applying vacuum pressure to the plurality of vacuum pads to individually place the plurality of devices into the plurality of tape pockets of the carrier tape.

In some embodiments, the processor may be further configured to control the taping head to position the plurality of devices a preset distance from the first camera in order for the first camera to capture the one or more images of the plurality of devices extracted by the taping head.

In some embodiments, the plurality of devices may be integrated circuits (ICs).

Another embodiment of the present disclosure provides a method comprising extracting, with a taping head, a plurality of devices from a plurality of tray pockets of a component tray; capturing, with a first camera, one or more images of the plurality of devices extracted by the taping head; determining, with a processor, size and orientation information of each of the plurality of devices extracted by the taping head based on the one or more images received from the first camera; determining, with the processor, a placement solution of the taping head to position the plurality of devices into a plurality of tape pockets of a carrier tape based on the size and orientation information of each of the plurality of devices; and placing, with the taping head, the plurality of devices into the plurality of tape pockets of the carrier tape according to the placement solution. The placement solution may comprise at least one corrective movement of the taping head and a drop sequence of placing each of the plurality of devices into the plurality of tape pockets of the carrier tape.

In some embodiments, the method may further comprise capturing, with a second camera, one or more images of the plurality of tape pockets of the carrier tape; determining, with the processor, dimension and position information of each of the plurality of tape pockets of the carrier tape based on the one or more images of the plurality of tape pockets of the carrier tape received from the second camera; and determining, with the processor, the solution space and boundaries of the plurality of tape pockets of the carrier tape based on the dimension and position information of each of the plurality of tape pockets.

In some embodiments, determining, with the processor, the placement solution of the taping head to position the plurality of devices into a plurality of tape pockets of a carrier tape based on the size and orientation information of each of the plurality of devices may comprise determining, with the processor, locations of a center point and four corners of each of the plurality of devices based on the size and orientation information of each of the plurality of devices; comparing, with the processor, the locations of the center point and four corners of each of the plurality of devices to a solution space and boundaries of each of the plurality of tape pockets of the carrier tape; and determining, with the processor, the corrective movement of the taping head to position the locations of the center point and four corners of each of the plurality of devices within the solution space and boundaries of each of the plurality of tape pockets of the carrier tape.

In some embodiments, determining, with the processor, the corrective movement of the taping head to position the locations of the center point and four corners of each of the plurality of devices within the solution space and boundaries of each of the plurality of tape pockets of the carrier tape may comprise determining, with the processor, a translational adjustment of the corrective movement to adjust an x, y position of the taping head such that the locations of the center point of each of the plurality of devices are within the solution space of each of the plurality of tape pockets of the carrier tape; and determining, with the processor, a rotational adjustment of the corrective movement to adjust an angle along a rotation axis of the taping head such that the locations of the four corners of each of the plurality of devices are within the boundaries of each of the plurality of tape pockets of the carrier tape.

In some embodiments, the plurality of devices may comprise N devices, and the drop sequence may comprise 1 to N drops. Determining, with the processor, the placement solution of the taping head to position the plurality of devices into a plurality of tape pockets of a carrier tape based on the size and orientation information of each of the plurality of devices may further comprise iteratively reducing, with the processor, the number of devices in a drop in the drop sequence when no single corrective movement of the taping head positions the locations of the center point and four corners of each of the plurality of devices within the solution space and boundaries of each of the plurality of tape pockets of the carrier tape; determining, with the processor, a corrective movement of the taping head to position the locations of the center point and four corners of each grouping of the plurality of devices within the solution space and boundaries of each corresponding grouping of the plurality of tape pockets of the carrier tape; and defining, with the processor, the drop sequence based on a number of groupings of the plurality of devices having a corresponding corrective movement.

In some embodiments, placing, with the taping head, the plurality of devices into the plurality of tape pockets of the carrier tape based on the placement solution may comprise placing, with the taping head, each grouping of the plurality of devices into each corresponding grouping of the plurality of tape pockets of the carrier tape according to the corresponding corrective movement and the drop sequence.

In some embodiments, the taping head may comprise a plurality of vacuum pads configured to individually engage each of the plurality of devices using vacuum pressure from a vacuum source. Extracting, with the taping head, the plurality of devices from the plurality of tray pockets of the component tray may comprise controlling, with the processor, the vacuum source to apply vacuum pressure to the plurality of vacuum pads to extract the plurality of devices from the plurality of tray pockets of the component tray. Placing, with the taping head, the plurality of devices into the plurality of tape pockets of the carrier tape based on the placement solution may comprise controlling, with the processor, the vacuum source to stop applying vacuum pressure to the plurality of vacuum pads to individually place the plurality of devices into the plurality of tape pockets of the carrier tape based on the corrective movement.

In some embodiments, the method may further comprise positioning, with the taping head, the plurality of devices at a preset distance from the first camera in order for the first camera to capture the one or more images of the plurality of devices extracted by the taping head.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system of an embodiment of the present disclosure, in which a plurality of devices are disposed in a component tray;

FIG. 2 is a further diagram of the system of FIG. 1, in which the plurality of devices are extracted from the component tray by a taping head;

FIG. 3 is a further diagram of the system of FIG. 1, in which the plurality of devices are placed into a carrier tape;

FIG. 4A is a top view of the component tray of FIG. 1;

FIG. 4B is a partial detail view of the component tray of FIG. 4A, in which a plurality of devices are disposed in a plurality of tray pockets of the component tray;

FIG. 5A is a top view of the carrier tape of FIG. 1;

FIG. 5B is a partial detail view of the carrier tape of FIG. 5A, in which a plurality of devices are disposed in a plurality of tape pockets of the carrier tape;

FIG. 6A is an exemplary image of the plurality of devices extracted by the taping head captured by the first camera in FIG. 2;

FIG. 6B is an exemplary image of a plurality of tape pockets of the carrier tape captured by the second camera in FIG. 2;

FIG. 7 is a flowchart of a method of an embodiment of the present disclosure;

FIG. 8 is a flowchart of a method of another embodiment of the present disclosure;

FIG. 9 is a flowchart of a method of another embodiment of the present disclosure;

FIG. 10 is a flowchart of a method of another embodiment of the present disclosure; and

FIG. 11 is a flowchart of a method of another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

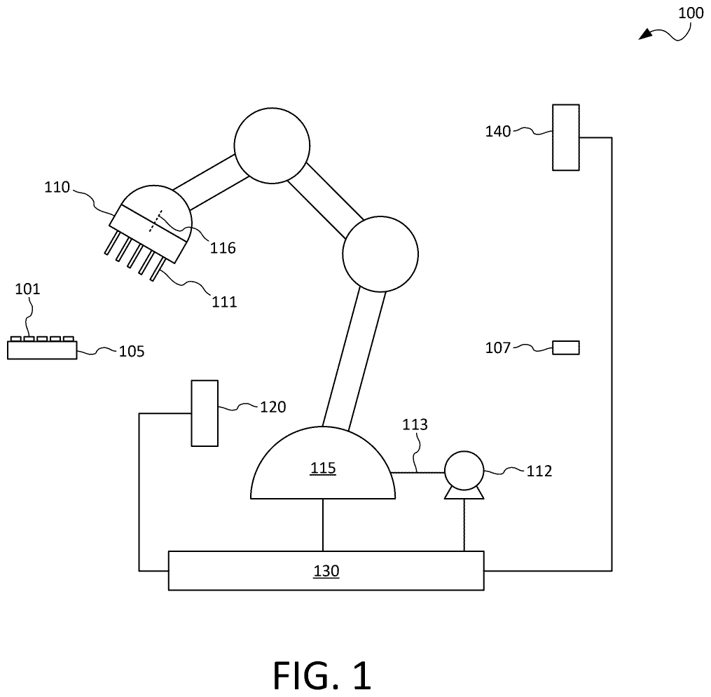

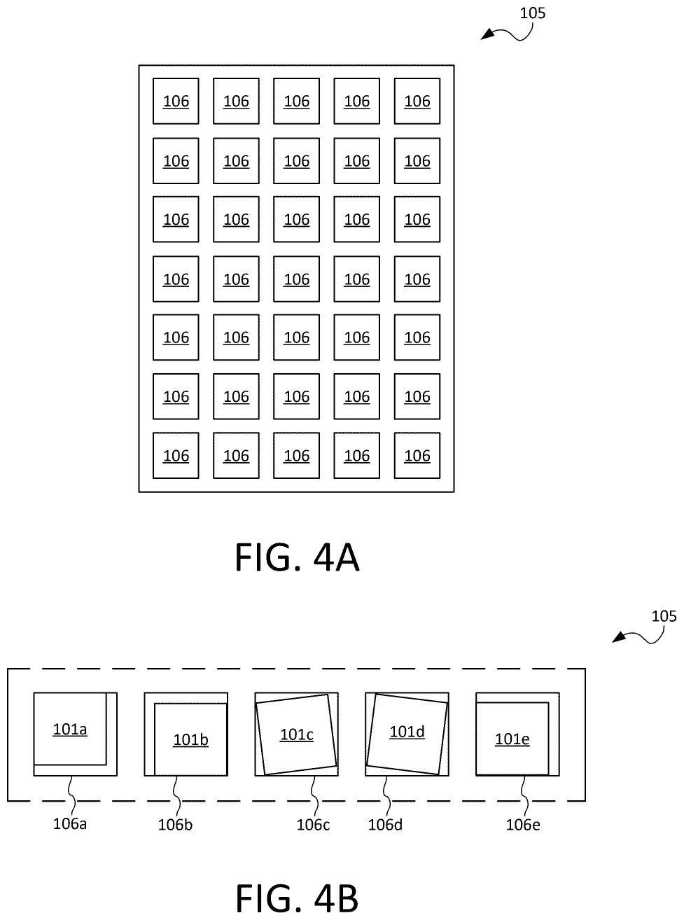

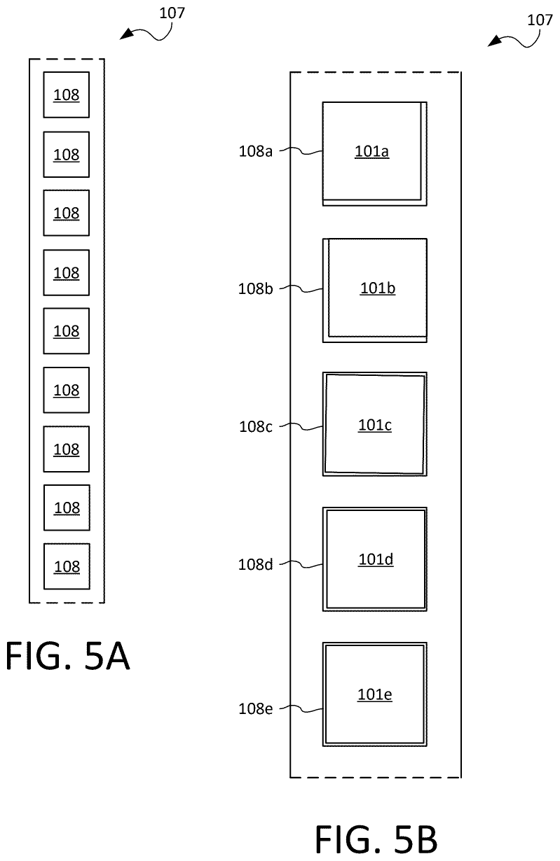

An embodiment of the present disclosure provides a system 100, as shown in FIGS. 1-3. The system 100 may be configured for handling a plurality of devices 101. The plurality of devices 101 may be electronic devices such as integrated circuits (ICs), chips, or other electrical components that can be handled by the system 100. The plurality of devices 101 may be disposed in a component tray 105. For example, each of the plurality of devices 101 may be individually arranged in respective ones of a plurality of tray pockets 106. As shown in FIG. 4A, the plurality of tray pockets 106 may be arranged in a rectangular array in the component tray 105, the number and specific arrangement of which is not limited herein. For example, the component tray 105 may be sized and arranged according to JEDEC (Joint Electronic Device Engineering Council) standards. As further described herein, the system 100 may be configured to transfer each of the plurality of devices 101 from the plurality of tray pockets 106 of the component tray 105 to a plurality of tape pockets 108 of a carrier tape 107. As shown in FIG. 5A, the plurality of tape pockets 108 may be arranged linearly in the carrier tape 107, the number and specific arrangement of which is not limited herein.

Referring to FIG. 1, the system 100 may comprise a taping head 110. The taping head 110 may be an end effector of a robot arm 115. The robot arm 115 may be configured to move the taping head 110 by actuating one or more joints of the robot arm 115 to position the taping head 110 within a volume defined by the envelope of the robot arm 115. The size and shape of the envelope of the robot arm 115 may depend on the arrangement of the robot arm 115 and its degrees of freedom. Although the robot arm 115 is shown as a polar robot in FIG. 1, it should be understood that the robot arm 115 may also include cartesian and cylindrical manipulators or the like, and is not limited herein. The robot arm 115 may be configured to move the taping head 110 in three translational directions within the volume (i.e., x, y, and z directions). In some embodiments, the robot arm 115 may only be configured to move the taping head 110 in two directions (e.g., y and z directions), while the third direction (e.g., x direction) is controlled by movement of the component tray 105 (i.e., tray indexing) and/or the carrier tape 107 (i.e., tape jogging) performed by other subsystems of the system 100. The robot arm 115 may be further configured to rotate the taping head 110 about a rotational axis 116 (i.e., by an angle θ). The component tray 105 may be disposed within the volume, such that the robot arm 115 can position the taping head 110 to extract the plurality of devices 101 from the plurality of tray pockets 106 of the component tray 105. In some embodiments, the component tray 105 may be indexed by a separate subsystem to position the plurality of devices 101 in the plurality of tape pockets 108 to be extracted by the taping head 110.

In some embodiments, the taping head 110 may comprise a plurality of vacuum pads 111. The plurality of vacuum pads 111 may be configured to individually engage each of the plurality of devices 101 based on vacuum pressure from a vacuum source 112. For example, in order to extract the plurality of devices 101 from the plurality of tray pockets 106 of the component tray 105, the vacuum source 112 may apply vacuum pressure to the plurality of vacuum pads 111. Accordingly, the plurality of devices 101 will remain engaged with the plurality of vacuum pads 111 as the robot arm 115 moves the taping head 110 within the volume. The vacuum source 112 may be controlled (e.g., by pneumatic valves) to stop applying vacuum pressure to one or more of the plurality of vacuum pads 111 to release a respective one of the plurality of devices 101 from the taping head 110. The plurality of vacuum pads 111 may be connected to the vacuum source 112 by a plurality of vacuum lines 113, which may be routed through the robot arm 115. The number of vacuum pads 111 may define the number of devices 101 that can be extracted by the taping head 110, which may depend on the size of the devices 101 and the yield of the system 100. Each of the plurality of vacuum pads 111 may have an area that is less than or equal to the area of the plurality of devices 101 to facilitate extraction by vacuum pressure.

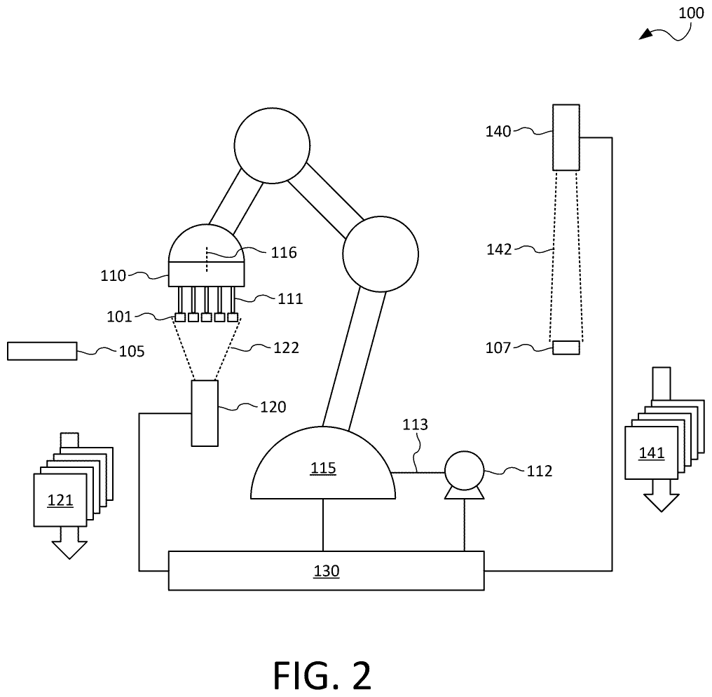

Referring to FIG. 2, the system 100 may further comprise a first camera 120. The first camera 120 may be a charge coupled device (CCD) camera, complementary metal oxide semiconductor (CMOS) sensor, or other type of sensor. The first camera 120 may be configured to capture one or more images 121 of the plurality of devices 101 extracted by the taping head 110. For example, the robot arm 115 may position the taping head 110 within the field of view 122 of the first camera 120, so that the first camera 120 can capture the one or more images 121 of the plurality of devices 101 extracted by the taping head 110. In some embodiments, the robot arm 115 may be configured to position the taping head 110 such that the plurality of devices 101 are at a preset distance from the first camera 120 to capture the one or more images 121 of the plurality of devices 101. The preset distance may depend on the arrangement of the robot arm 115 and the first camera 120 within the system 100 and the resolution, focal length, and field of view of the first camera 120. For example, the preset distance may be equal to a focal distance of the first camera 120. By positioning the plurality of devices 101 at the preset distance, the plurality of devices 101 may be consistently captured within the one or more images 121 for efficient image processing.

The system 100 may further comprise a processor 130. The processor 130 may include a microprocessor, a microcontroller, or other devices.

The processor 130 may be coupled to the components of the system 100 in any suitable manner (e.g., via one or more transmission media, which may include wired and/or wireless transmission media) such that the processor 130 can receive output. The processor 130 may be configured to perform a number of functions using the output. An inspection tool can receive instructions or other information from the processor 130. The processor 130 optionally may be in electronic communication with another inspection tool, a metrology tool, a repair tool, or a review tool (not illustrated) to receive additional information or send instructions.

The processor 130 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 130 may be disposed in or otherwise part of the system 100 or another device. In an example, the processor 130 may be part of a standalone control unit or in a centralized quality control unit. Multiple processors 130 may be used, defining multiple subsystems of the system 100.

The processor 130 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 130 to implement various methods and functions may be stored in readable storage media, such as a memory.

If the system 100 includes more than one subsystem, then the different processors 130 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 130 may be configured to perform a number of functions using the output of the system 100 or other output. For instance, the processor 130 may be configured to send the output to an electronic data storage unit or another storage medium. The processor 130 may be further configured as described herein.

The processor 130 may be configured according to any of the embodiments described herein. The processor 130 also may be configured to perform other functions or additional steps using the output of the system 100 or using images or data from other sources.

The processor 130 may be communicatively coupled to any of the various components or sub-systems of system 100 in any manner known in the art. Moreover, the processor 130 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 130 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 130 (or computer subsystem) or, alternatively, multiple processors 130 (or multiple computer subsystems). Moreover, different sub-systems of the system 100 may include one or more computing or logic systems. Therefore, the above description should not be interpreted as a limitation on the present disclosure but merely an illustration.

The processor 130 may be in electronic communication with the taping head 110 and the first camera 120. For example, the processor 130 may be configured to send instructions to the robot arm 115 to control movement of the taping head 110. In particular, the processor 130 may be configured to send instructions to the robot arm 115 to move the taping head 110 to extract the plurality of devices 101 from the plurality of tray pockets 106 of the component tray 105 and to move the taping head 110 to position the plurality of devices 101 at the preset distance from the first camera 120. In some embodiments, the processor 130 may be configured to control the vacuum source 112 to apply vacuum pressure to the plurality of vacuum pads 111 to extract the plurality of devices 101 from the plurality of tray pockets 106 of the component tray 105 and to stop applying vacuum pressure to the plurality of vacuum pads 111 to release the plurality of devices 101 from the taping head 110. In some embodiments, the processor 130 may be configured to send instructions to one or more motors or actuators to index the component tray 105 to a position where the plurality of devices 101 can be extracted from the plurality of tray pockets 106 by the taping head 110. In some embodiments, the processor 130 may be configured to send instructions to one or more actuators to jog the carrier tape 107 to position the plurality of tape pockets 108 to receive the plurality of devices 101. The processor 130 may be further configured to send instructions to the first camera 120 to capture the one or more images 121 of the plurality of devices 101 extracted by the taping head 110 and to receive the one or more images 121 captured by the first camera 120. In particular, the processor 130 may be configured to send instructions to the first camera 120 to capture the one or more images 121 of the plurality of devices 101 extracted by the taping head 110 when the robot arm 115 has moved the taping head 110 to position the plurality of device 101 at the preset distance from the first camera 120.

The processor 130 may be configured to determine size and orientation information of each of the plurality of devices 101 extracted by the taping head 110 based on the one or more images 121 of the plurality of devices 101 received from the first camera 120. For example, image segmentation may be used to identify the edges of the plurality of devices 101, which can be used to determine the size and orientation information of each of the plurality of devices 101. Other ways of determining the size and orientation information of the plurality of devices 101 are possible and may depend on the type of IC or other device of the plurality of devices 101 that is being processed by the system 100. It should be understood that based on manufacturing tolerances, the size of each of the plurality of devices 101 may differ. In addition, the tolerances in the size of each of the plurality of tray pockets 106 of the component tray 105 may differ, which can allow the orientation and position of the plurality of devices 101 to differ within each of the plurality of tray pockets 106. Accordingly, when the taping head 110 extracts the plurality of devices 101 from the plurality of tray pockets 106 of the component tray 105, the plurality of devices 101 may be off-center and/or rotationally misaligned (as shown in FIG. 4B), and centering the taping head 110 within the plurality of tape pockets 108 of the carrier tape 107 could result in misplacement of the plurality of devices 101. The plurality of tape pockets 108 of the carrier tape 107 may also be smaller than the plurality of tray pockets 106 of the component tray 105 or may have different tolerances due to industry standards, which, when combined with manufacturing tolerances, can make misalignment more likely. By determining the size and orientation information of each of the plurality of devices 101 extracted by the taping head 110, the system 100 may have feedback to use to prevent misplacements when placing the plurality of devices 101 into the plurality of tape pockets 108 of the carrier tape 107.

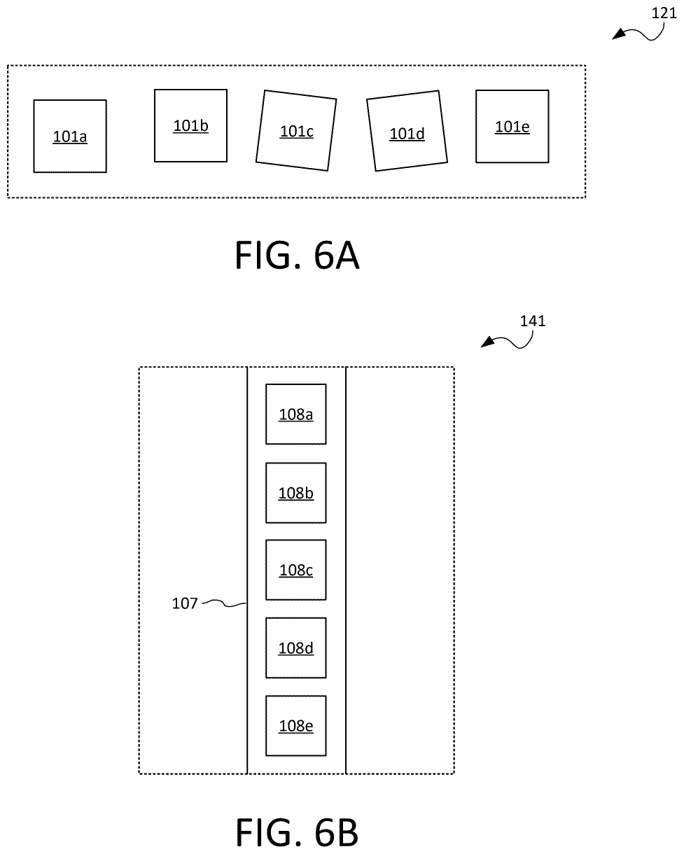

In an example, the plurality of devices 101 disposed in the component tray 105 may comprise a first device 101a, a second device 101b, a third device 101c, a fourth device 101d, and a fifth device 101e, disposed in a first tray pocket 106a, a second tray pocket 106b, a third tray pocket 106c, a fourth tray pocket 106d, and a fifth tray pocket 106e, respectively, as shown in FIG. 4B. Each of the first device 101a, the second device 101b, the third device 101c, the fourth device 101d, and the fifth device 101e may be extracted by the taping head 110 and may have individual misalignment. Using the image 121 of the first device 101a, the second device 101b, the third device 101c, the fourth device 101d, and the fifth device 101e shown in FIG. 6A (which is a bottom view of these devices), the processor 130 can determine the size and orientation information of each device extracted by the taping head 110 in relation to their corresponding connector to the taping head 110 (e.g., one of the plurality of vacuum pads 111).

The processor 130 may be further configured to determine a placement solution of the taping head 110 to position each of the plurality of devices 101 into the plurality of tape pockets 108 of the carrier tape 107 based on the size and orientation information of each of the plurality of devices 101. The placement solution may comprise at least one corrective movement of the taping head 110 and a drop sequence of placing each of the plurality of devices 101 into the plurality of tape pockets 108 of the carrier tape 107. The at least one corrective movement may comprise a translational adjustment (i.e., adjustment of the position of the taping head 110 in the x direction or y direction) and/or a rotational adjustment (i.e., adjustment of the rotation of the taping head 110 along the rotation axis 116 by the angle θ) relative to the to the plurality of tape pockets 108 of the carrier tape 107. In other words, the corrective movement may be defined as (x, y, θ), where x, y, and θ are positive or negative values that are applied to the control instruction sent by the processor 130 to the robot arm 115 when moving the taping head 110 to place the plurality of devices 101 into the plurality of tape pockets 108 of the carrier tape 107. In some embodiments, the placement solution may further comprise a translation adjustment of the position of the carrier tape 107. The processor 130 may be configured to send instructions to one or more actuators or motors to move the carrier tape 107 in accordance with the placement solution. For example, jogging the carrier tape 107 may move the plurality of tape pockets 108 in one direction of the corrective movement (e.g., x direction) while the robot arm 115 moves in the other directions (e.g., y direction and angle θ) to position the plurality of devices 101 into the plurality of tape pockets 108 of the carrier tape 107.

It should be understood that the corrective movement may be a global adjustment of the position of the taping head 110, not an individual adjustment of each of the plurality of devices 101 extracted by the taping head 110. For example, a translational adjustment would adjust the x, y positions of each of the plurality of devices 101 extracted by the taping head 110 by the same value, and a rotational adjustment would adjust the angle θ of the taping head 110, thereby adjusting the rotational position of each of the plurality of devices 101 extracted by the taping head 110 based on their distance from the rotation axis 116. Accordingly, the drop sequence of placing each of the plurality of devices 101 into the plurality of tape pockets 108 of the carrier tape 107 may include a single drop (i.e., where each of the plurality of devices 101 can be placed into the plurality of tape pockets 108 of the carrier tape 107 simultaneously, with a single corrective movement (x, y, θ)) or multiple drops (i.e., where some of the plurality of devices 101 are placed into some of the plurality of tape pockets 108 of the carrier tape 107 with a corrective movement (x, y, θ), followed by the remaining of the plurality devices 101 with subsequent corrective movement(s) (x, y, θ)).

The processor 130 may be configured to determine the placement solution based on the size and orientation information of each of the plurality of the devices 101 determined from the one or more images 121 of the plurality of devices 101 received from the first camera 120. For example, the processor 130 may determine the locations of the center point and four corners of each of the plurality devices 101 based on the size and orientation information of each of the plurality of devices 101 and may compare the locations of the center point and four corners of each of the plurality devices 101 to a solution space and boundaries of each of the plurality of tape pockets 108 of the carrier tape 107. The solution space may be defined as an area of a tape pocket in which the center point of a device and the four corners of the device can be placed in a valid drop condition. The boundaries may be defined as the perimeter of the tape pocket. If the locations of the center point of each of the plurality of devices 101 are within the solution space and the locations of the four corners of each of the plurality of devices 101 are within the boundaries of each of the plurality of tape pockets 108 of the carrier tape 107, the processor 130 may determine that the plurality of devices 101 can be placed in the plurality of tape pockets 108 of the carrier tape 107 without risk of misplacement. If the locations of the center point of each of the plurality of devices 101 are not within the solution space and/or the locations of the four corners of each of the plurality of devices 101 are not within the boundaries of each of the plurality of tape pockets 108 of the carrier tape 107, the processor 130 may determine a corrective movement (x, y, θ) to adjust the x, y position of the taping head 110 such that the locations of the center point of each of the plurality of devices 101 are within the solution space of each of the plurality of tape pockets 108 of the carrier tape 107 and/or to adjust the angle θ along the rotation axis of the taping head 110 such that the locations of the four corners of each of the plurality of devices 101 are within the boundaries of each of the plurality of tape pockets 108 of the carrier tape 107. If a single corrective movement (x, y, θ) fails to result in a placement solution, the processor 130 may determine a placement solution by increasing the number of drops in the drop sequence and comparing the locations of the center point and four corners of groups of devices of the plurality of devices 101 to the solution space and boundaries of a corresponding group of tape pockets of the plurality of tape pockets 108 of the carrier tape 107 to find a corrective movement (x, y, θ) for each group of devices of the plurality of devices 101 in each drop.

In some embodiments, the processor 130 may be configured to optimize the placement solution to reduce the number of drops in the drop sequence of placing each of the plurality of devices 101 into the plurality of tape pockets 108 of the carrier tape 107. For example, for a plurality of devices 101 that includes N devices, a placement solution may include a sequence of 1 to N drops, in which 1 drop (i.e., simultaneously placing all N devices with a single corrective movement (x, y, θ)) may be the most efficient/fastest placement solution and N drops (i.e., individually placing each of the N devices with N corrective movements (x, y, θ)) may be the least efficient/slowest placement solution. Accordingly, the processor 130 may optimize the placement solution by first determining whether a single drop solution exists, and then iteratively reducing the number of devices in the drop (i.e., N−1, N−2, . . . , N−(N−1)) to determine the drop sequence of placing each of the plurality of devices 101 into the plurality of tape pockets 108 of the carrier tape 107 with a minimum number of drops. In each iteration, the processor 130 may consider whether a single corrective movement (x, y, θ) will cause the locations of the center points and four corners of each possible grouping of the plurality of devices 101 to be within the solution space and boundaries of the corresponding grouping of the plurality of tape pockets 108 of the carrier tape 107 before further reducing the number of devices in the group and increasing the number of drops. For example, for N=5, the processor 130 may analyze each N−1 grouping (i.e., 4 of 5) before analyzing smaller groups of N−2, etc., in order to maximize the number of devices dropped simultaneously. In particular, example drop sequences for N=5 may include one drop (all 5 devices), two drops (4 devices then 1 device, or three devices then two devices), three drops (two devices, then two devices, then one device, or three devices, then two single device drops), four drops (two devices then three single device drops) or five drops (five single device drops), the order of which is not limited herein. The processor 130 may be configured to define the drop sequence based on the number of groupings of the plurality of devices having a corresponding corrective movement.

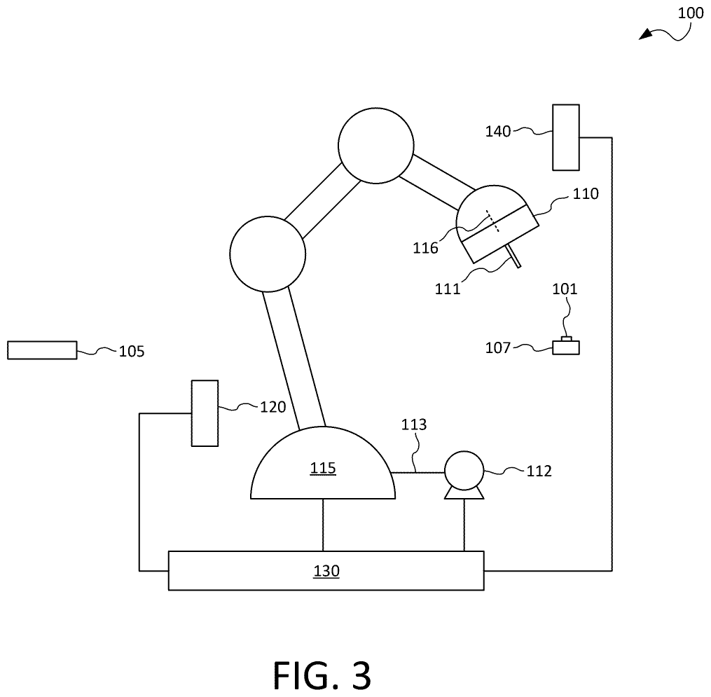

Referring to FIG. 3, the processor 130 may be configured to control the taping head 110 to place the plurality of devices 101 into the plurality of tape pockets 108 of the carrier tape 107 according to the placement solution. In particular, the processor 130 may send instructions to the robot arm 115 to move the taping head 110 and/or to the one or more motors or actuators to move the carrier tape 107 according to the corrective movement(s) (x, y, θ) and the drop sequence to place each of the plurality of devices 101 into the plurality of tape pockets 108 of the carrier tape 107. For example, as shown in FIG. 5B, the first device 101a, the second device 101b, the third device 101c, the fourth device 101d, and the fifth device 101e may be placed in the first tape pocket 108a, the second tape pocket 108b, the third tape pocket 108c, the fourth tape pocket 108d, and the fifth tape pocket 108e of the carrier tape 107. In some embodiments, the processor 130 may be configured to control the vacuum source 112 to stop applying vacuum pressure to the plurality of vacuum pads 111 to individually place the plurality of devices 101 into the plurality of tape pockets 108 of the carrier tape 107. In other words, the processor 130 may control the vacuum source 112 to stop applying vacuum to groups of pads of the plurality of vacuum pads 111 according to a group of devices of the plurality of devices 101 that can be dropped with a single corrective movement (x, y, θ) according to the placement solution, while applying vacuum pressure to the remaining pads to hold the remaining devices on the taping head 110 for the next drop in the sequence.

In some embodiments, the system 100 may further comprise a second camera 140. The second camera 140 may be a charge coupled device (CCD) camera, complementary metal oxide semiconductor (CMOS) sensor, or other type of sensor. Referring to FIG. 2, the second camera 140 may be configured to capture one or more images 141 of the plurality of tape pockets 108 of the carrier tape 107. For example, the second camera 140 may be positioned such that the plurality of tape pockets 108 of the carrier tape 107 are within the field of view 142 of the second camera 140. The distance between the second camera 140 and the carrier tape 107 may depend on the resolution, focal length, and field of view of the second camera 140, and space required for the taping head 110 to place the plurality of devices 101 into the plurality of tape pockets 108 of the carrier tape 107. In some embodiments, the second camera 140 may be disposed on the taping head 110, such that the robot arm 115 is configured to move the second camera 140 as it moves the taping head 110. Accordingly, the robot arm 115 may be configured to position the second camera 140 such that the plurality of tape pockets 108 of the carrier tape 107 are within the field of view 142 of the second camera 140. Alternatively, the second camera 140 may be at a fixed position in the system 100 independent from the robot arm 115. The processor 130 may be configured to send instructions to the second camera 104 to capture the one or more images 141 of the plurality of tape pockets 108 of the carrier tape 107, and the processor 130 may receive the one or more images 141 of the plurality of tape pockets 108 of the carrier tape 107 from the second camera 140. For example, the processor 130 may be configured to send instructions to the second camera 140 to capture the one or more images 141 of the plurality of tape pockets 108 of the carrier tape 107 before sending the instructions to the robot arm 115 to move the taping head 110 to extract the plurality of devices 101 from the plurality of tray pockets 106 of the component tray 105 or before sending the instructions to the robot arm 115 to move the taping head 110 to place the plurality of devices 101 into the plurality of tape pockets 108 of the carrier tape 107. In some embodiments, the processor 130 may be configured to send instructions to the second camera 140 to capture the one or more images 141 of the plurality of tape pockets 108 of the carrier tape 107 after sending instructions to the robot arm 115 to move the taping head (and the second camera 140 connected thereto) to a position in which the plurality of tape pockets 108 are within the field of view 142 of the second camera 140. In some embodiments, the processor 130 may be configured to send instructions to the second camera 140 to capture the one or more images 141 of the plurality of tape pockets 108 of the carrier tape 107 at the same time that the instructions are sent to the first camera 120 to capture the one or more images 121 of the plurality of devices 101 extracted by the taping head 110, for example, where the second camera 140 is at a fixed position independent of the taping head 110.

In an example, the plurality of tape pockets 108 of the carrier tape 107 may comprise a first tape pocket 108a, a second tape pocket 108b, a third tape pocket 108c, a fourth tape pocket 108d, and a fifth tape pocket 108e configured to receive each of the first device 101a, the second device 101b, the third device 101c, the fourth device 101d, and the fifth device 101e, respectively. Using the image of the carrier tape 107 (shown in FIG. 6B), the processor 130 can determine dimension and position information of the first tape pocket 108a, the second tape pocket 108b, the third tape pocket 108c, the fourth tape pocket 108d, and the fifth tape pocket 108e.

The processor 130 may be further configured to determine dimension and position information of the plurality of tape pockets 108 of the carrier tape 107 based on the one or more images 141 of the plurality of tape pockets 108 received from the second camera 140. It should be understood that based on manufacturing tolerances, the dimension and position information of each of the plurality of tape pockets 108 of the carrier tape 107 may differ. Consequently, the solution space and boundaries of each of the plurality of tape pockets 108 may differ. The processor 130 may therefore determine the solution space and boundaries of each of the plurality of tape pockets 108 based on the dimension and position information of each of the plurality of tape pockets 108, which can be used to determine the placement solution. For example, image segmentation may be used to identify the boundaries of the plurality of tape pockets 108, which can be used to determine the dimension and position information of each of the plurality of tape pockets 108. Other ways of determining the dimension and position information of the plurality of tape pockets 108 are possible and may depend on the type of carrier tape 107 being processed by the system 100. Accordingly, the system 100 may analyze each of the plurality of devices 101 and each of the plurality of tape pockets 108 to confirm proper alignment when placing and to avoid placement errors.

It should be understood that after the plurality of devices 101 extracted by the taping head 110 are placed into the plurality of tape pockets 108 of the carrier tape 107, the carrier tape 107 may be advanced/jogged (e.g., by instructions sent from the processor 130 to one or more actuators or motors) to move additional tape pockets to a position to be loaded, and the taping head 110 can extract additional devices from the component tray 105 to be placed in the additional tape pockets of the carrier tape 107 by repeating the functions described above.

With the system 100, feedback from the image 121 of the plurality of devices 101 captured by first camera 120 can be used to determine a placement solution for the taping head 110 to place each of the plurality of devices 101 into the plurality of tape pockets 108 of the carrier tape 107, which avoids misalignment of the taping head 110 and misplacement of the plurality of devices 101. Further feedback from the image 141 of the plurality of tape pockets 108 of the carrier tape 107 captured by the second camera 140 can be used with the image 121 of the plurality of devices 101 captured by first camera 120 to determine the placement solution to improve placement. Accordingly, processing time may be reduced for improved yield.

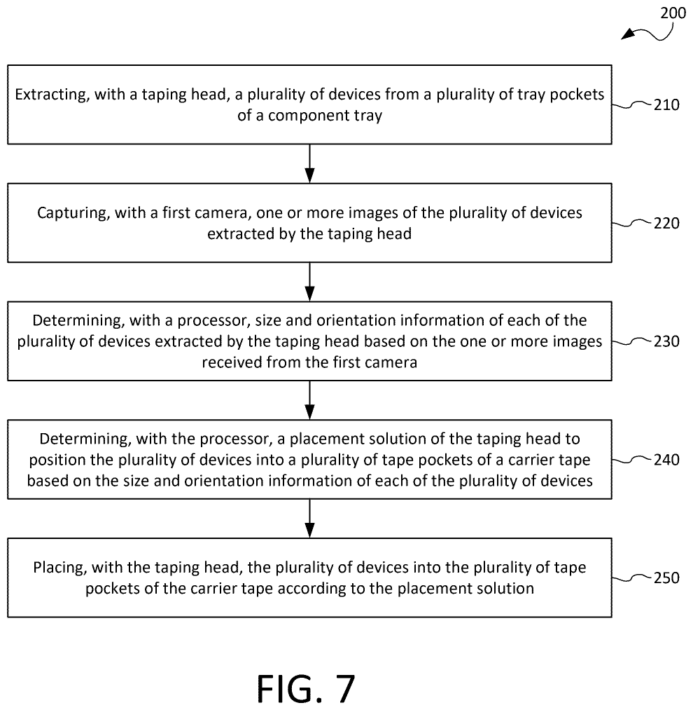

Another embodiment of the present disclosure provides a method 200. As shown in FIG. 7, the method 200 may comprise the following steps.

At step 210, a taping head extracts a plurality of devices from a plurality of tray pockets of a component tray. The plurality of devices may be electronic devices such as integrated circuits (ICs), chips, or other electrical components. The plurality of devices may be disposed in a component tray. For example, each of the plurality of devices may be individually arranged in respective ones of a plurality of tray pockets. As shown in FIG. 4A, the plurality of tray pockets may be arranged in a rectangular array in the component tray, the number and specific arrangement of which is not limited herein. For example, the component tray 105 may be sized and arranged according to JEDEC (Joint Electronic Device Engineering Council) standards. The taping head may be an end effector of a robot arm. The robot arm may be configured to move the taping head to position the taping head within a volume defined by the envelope of the robot arm. The robot arm may be a polar robot or may include a combination of cartesian and cylindrical manipulators or the like, and is not limited herein. The size and shape of the envelope of the robot arm may depend on the arrangement of the robot arm and its degrees of freedom. The robot arm may be configured to move the taping head in three translational directions within the volume (i.e., x, y, and z directions). In some embodiments, the robot arm may only be configured to move the taping head in two directions (e.g., y and z directions), while the third direction (e.g., x direction) is controlled by movement of the component tray (i.e., tray indexing) and/or the carrier tape (i.e., tape jogging). The robot arm may be further configured to rotate the taping head about a rotational axis (i.e., by an angle θ). The component tray may be disposed within the volume, such that the robot arm can position the taping head to extract the plurality of devices from the plurality of tray pockets of the component tray. In some embodiments, the component tray may be indexed to position the plurality of devices in the plurality of tray pockets to be extracted by the taping head.

At step 220, a first camera captures one or more images of the plurality of devices extracted by the taping head. The first camera may be a charge coupled device (CCD) camera, complementary metal oxide semiconductor (CMOS) sensor, or other type of sensor. The robot arm may position the taping head within the field of view of the first camera, so that the first camera can capture the one or more images of the plurality of devices extracted by the taping head.

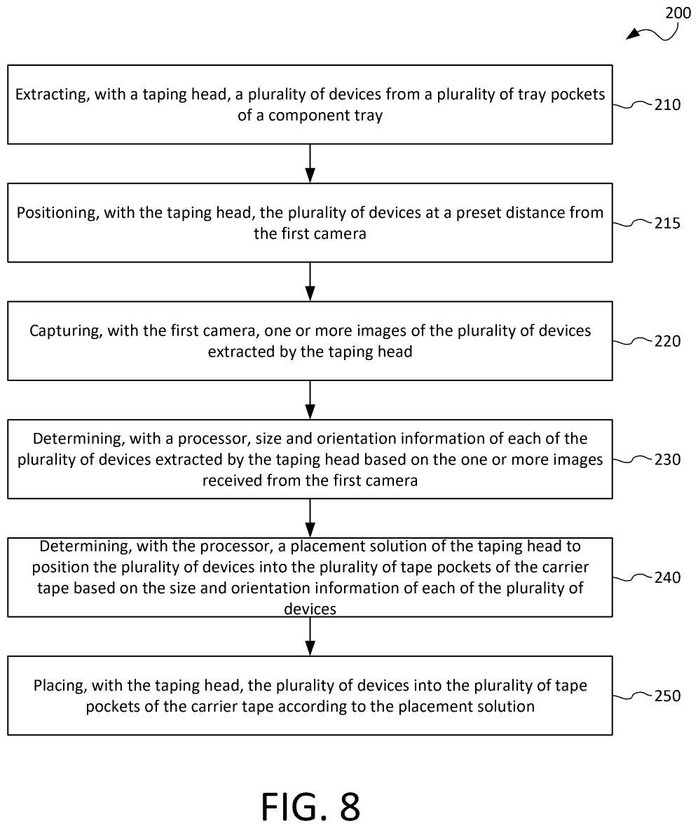

In some embodiments, before step 220, the method 200 may further comprise step 215, as shown in FIG. 8. At step 215, the taping head positions the plurality of devices at a preset distance from the first camera in order for the first camera to capture the one or more images of the plurality of devices extracted by the taping head. The robot arm may be configured to position the taping head such that the plurality of devices 101 are at the preset distance from the first camera. The preset distance may depend on the arrangement of the robot arm and the first camera 120 within the system, and the resolution, focal length, and field of view of the first camera. For example, the preset distance may be equal to the focal distance of the first camera. By positioning the plurality of devices at the preset distance, the plurality of devices may be consistently captured within the one or more images for efficient image processing.

At step 230, a processor determines size and orientation information of each of the plurality of devices extracted by the taping head based on the one or more images received from the first camera. For example, image segmentation may be used to identify the edges of the plurality of devices, which can be used to determine the size and orientation information of each of the plurality of devices. Other ways of determining the size and orientation information of the plurality of devices are possible and may depend on the type of IC or other device of the plurality of devices is being processed with the method 200. It should be understood that based on manufacturing tolerances, the size of each of the plurality of devices may differ. In addition, the tolerances in the size of each of the plurality of tray pockets of the component tray may differ, which can allow the orientation and position of the plurality of devices to differ within each of the plurality of tray pockets. Accordingly, when the taping head extracts the plurality of devices from the plurality of tray pockets of the component tray, the plurality of devices may be off-center and/or rotationally misaligned (as shown in FIG. 4B), and centering the taping head with the plurality of tape pockets of the carrier tape could result in misplacement of the plurality of devices. The plurality of tape pockets of the carrier tape may also be smaller than the plurality of tray pockets of the component tray or may have different tolerances due to industry standards, which, when combined with manufacturing tolerances, can make misalignment more likely. By determining the size and orientation information of each of the plurality of devices extracted by the taping head, the system may have feedback to use to prevent misplacements when placing the plurality of devices into the plurality of tape pockets of the carrier tape.

At step 240, the processor determines a placement solution of the taping head to position the plurality of devices into a plurality of tape pockets of a carrier tape based on the size and orientation information of each of the plurality of devices. The placement solution may comprise at least one corrective movement of the taping head and a drop sequence of placing each of the plurality of devices into the plurality of tape pockets of the carrier tape. The at least one corrective movement may comprise a translational adjustment (i.e., adjustment of the position of the taping head in the x direction or y direction) and/or a rotational adjustment (i.e., adjustment of the rotation of the taping head along the rotation axis by the angle θ) relative to the to the plurality of tape pockets of the carrier tape. In other words, the corrective movement may be defined as (x, y, θ), where x, y, and θ are positive or negative values that are applied to the control instruction sent by the processor to the robot arm when moving the taping head to place the plurality of devices into the plurality of tape pockets of the carrier tape. In some embodiments, the placement solution includes movement of the carrier tape. For example, jogging the carrier tape may move the plurality of tape pockets in one direction of the corrective movement (e.g., x direction) while the robot arm moves in the other directions (e.g., y direction and angle θ) to position the plurality of devices into the plurality of tape pockets of the carrier tape.

It should be understood that the corrective movement may be a global adjustment of the position of the taping head, not an individual adjustment of each of the plurality of devices extracted by the taping head. For example, a translational adjustment would adjust the x, y positions of each of the plurality of devices extracted by the taping head by the same value, and a rotational adjustment would adjust the angle θ of the taping head, thereby adjusting the rotational position of each of the plurality of devices extracted by the taping head based on their distance from the rotation axis 116. Accordingly, the drop sequence of placing each of the plurality of devices into the plurality of tape pockets of the carrier tape may include a single drop (i.e., where each of the plurality of devices can be placed into the plurality of tape pockets of the carrier tape simultaneously, with a single corrective movement (x, y, θ)) or multiple drops (i.e., where some of the plurality of devices are placed into some of the plurality of tape pockets of the carrier tape with a corrective movement (x, y, θ), followed by the remaining of the plurality devices with subsequent corrective movement(s) (x, y, θ)).

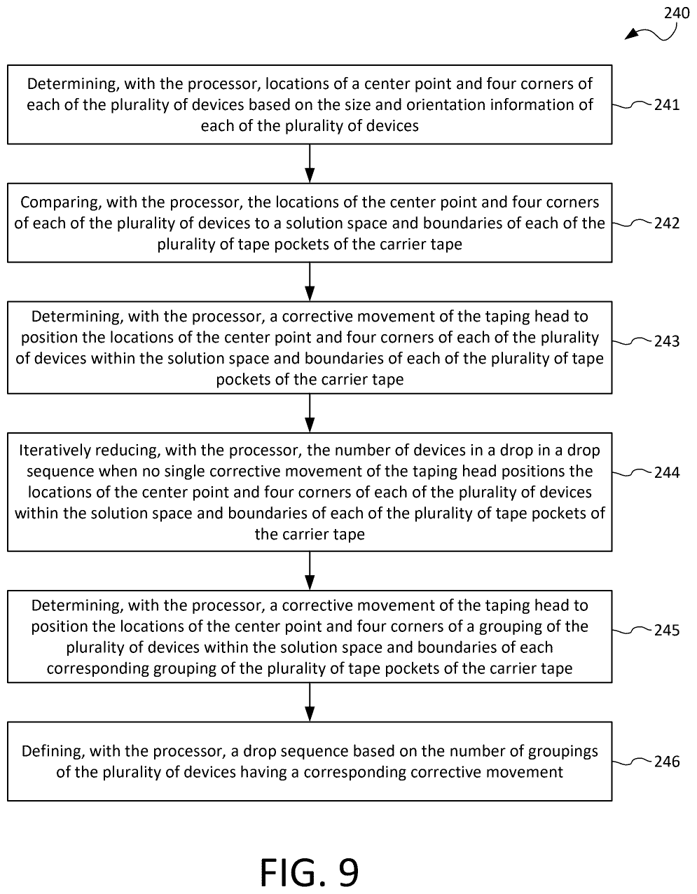

In some embodiments, step 240 may comprise the following steps, shown in FIG. 9.

At step 241, the processor determines locations of a center point and four corners of each of the plurality of devices based on the size and orientation information of each of the plurality of devices.

At step 242, the processor compares the locations of the center point and four corners of each of the plurality of devices to a solution space and boundaries of each of the plurality of tape pockets of the carrier tape. The solution space may be defined as an area of a tape pocket in which the center point of a device and the four corners of the device can be placed in a valid drop condition. The boundaries may be defined as the perimeter of the tape pocket. If the locations of the center point of each of the plurality of devices are within the solution space and the locations of the four corners of each of the plurality of devices are within the boundaries of each of the plurality of tape pockets of the carrier tape, the processor may determine that the plurality of devices can be placed the plurality of tape pockets of the carrier tape without risk of misplacement. If the locations of the center point of each of the plurality of devices are not within the solution space and/or the locations of the four corners of each of the plurality of devices are not within the boundaries of each of the plurality of tape pockets of the carrier tape, the processor may determine a corrective movement.

At step 243, the processor determines the corrective movement of the taping head to position the locations of the center point and four corners of each of the plurality of devices within the solution space and boundaries of each of the plurality of tape pockets of the carrier tape.

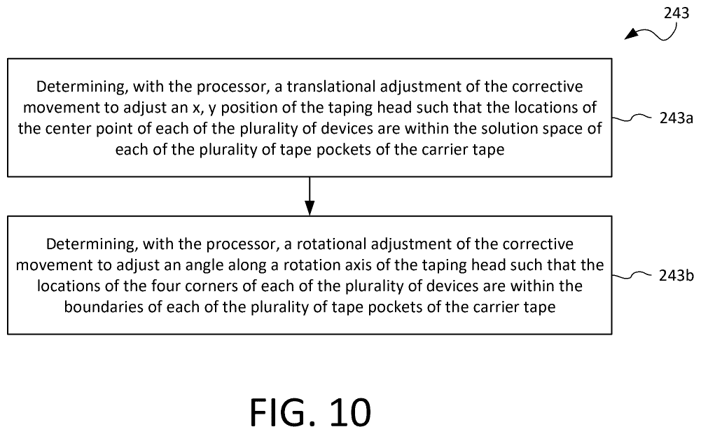

In some embodiments, step 243 may comprise the following steps, shown in FIG. 10.

At step 243a, the processor determines a translational adjustment of the corrective movement to adjust an x, y position of the taping head such that the locations of the center point of each of the plurality of devices are within the solution space of each of the plurality of tape pockets of the carrier tape. In some embodiments, the translational adjustment of the corrective movement may be provided by jogging the carrier tape to adjust the position of the plurality of tape pockets.

At step 243b, the processor determines a rotational adjustment of the corrective movement to adjust an angle along a rotation axis of the taping head such that the locations of the four corners of each of the plurality of devices are within the boundaries of each of the plurality of tape pockets of the carrier tape.

In some instances, a single corrective movement (x, y, θ) may fail to result in a placement solution. Accordingly, step 240 may comprise the following additional steps, shown in FIG. 9.

At step 244, the processor iteratively reduces the number of devices in a drop in the drop sequence when no single corrective movement of the taping head positions the locations of the center point and four corners of each of the plurality of devices within the solution space and boundaries of each of the plurality of tape pockets of the carrier tape.

At step 245, the processor determines a corrective movement of the taping head to position the locations of the center point and four corners of each grouping of the plurality of devices within the solution space and boundaries of each corresponding grouping of the plurality of tape pockets of the carrier tape.

At step 246, the processor defines the drop sequence based on the number of groupings of the plurality of devices having a corresponding corrective movement. By increasing the number of drops in the drop sequence and comparing the locations of the center point and four corners of groups of devices of the plurality of devices to the solution space and boundaries of a corresponding group of tape pockets of the plurality of tape pockets of the carrier tape to find a corrective movement (x, y, θ) for each group of devices of the plurality of devices in each drop, the processor may determine a placement solution in which all devices extracted by the taping head can be placed in the plurality of tape pockets of the carrier tape.

Steps 244 to 246 may optimize the placement solution to reduce the number of drops in the drop sequence. For example, for a plurality of devices that includes N devices, a placement solution may include a sequence of 1 to N drops, in which 1 drop (i.e., simultaneously placing all N devices with a single corrective movement (x, y, θ)) may be the most efficient/fastest placement solution and N drops (i.e., individually placing each of the N devices with N corrective movements (x, y, θ)) may be the least efficient/slowest placement solution. Accordingly, the placement solution may be optimized by first determining whether a single drop solution exists, and then iteratively reducing the number of devices in the drop (i.e., N−1, N−2, . . . , N−(N−1)) to determine the drop sequence having a minimum number of drops. In each iteration, it may be determined at step 245 whether a single corrective movement (x, y, θ) will cause the locations of the center points and four corners of each possible grouping of the plurality of devices to be within the solution space and boundaries of the corresponding grouping of the plurality of tape pockets of the carrier tape before further reducing the number of devices in the group and increasing the number of drops. For example, for N=5, each N−1 grouping (i.e., 4 of 5) can be analyzed before analyzing smaller groups of N−2, etc., in order to maximize the number of devices dropped simultaneously. In particular, example drop sequences for N=5 may include one drop (all 5 devices), two drops (4 devices then 1 device, or three devices then two devices), three drops (two devices, then two devices, then one device, or three devices, then two single device drops), four drops (two devices then three single device drops) or five drops (five single device drops), the order of which is not limited herein. The drop sequence may be defined based on the number of groupings of the plurality of devices having a corresponding corrective movement.

At step 250, the taping head places the plurality of devices into the plurality of tape pockets of the carrier tape according to the placement solution. The robot arm may move the taping head according to the corrective movement(s) (x, y, θ) and the drop sequence to place each of the plurality of devices into the plurality of tape pockets of the carrier tape.

In some embodiments, step 250 may comprise placing, with the taping head, each grouping of the plurality of devices into each corresponding grouping of the plurality of tape pockets of the carrier tape according to the corresponding corrective movement and the drop sequence. Accordingly, all N devices of the plurality of devices can be placed into the plurality of tape pockets with the corresponding corrective movements and drop sequence of the placement solution.

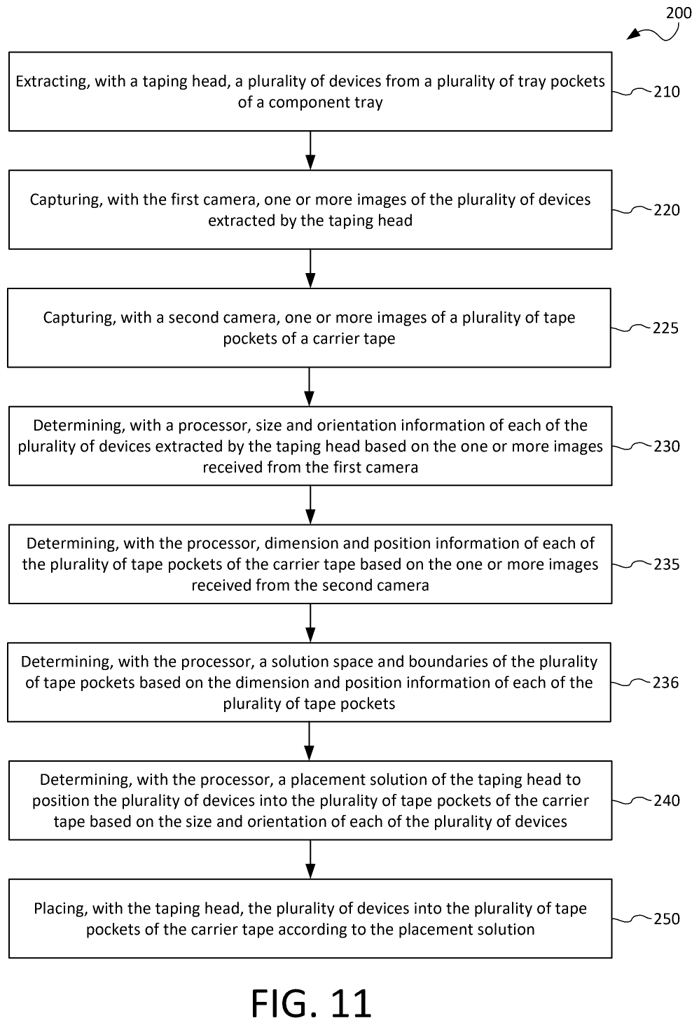

In some embodiments, the method 200 may comprise the following additional steps shown in FIG. 11.

At step 225, a second camera captures one or more images of the plurality of tape pockets of the carrier tape. The second camera 140 may be a charge coupled device (CCD) camera, complementary metal oxide semiconductor (CMOS) sensor, or other type of sensor. The second camera may be positioned such that the plurality of tape pockets of the carrier tape are within the field of view of the second camera. In some embodiments, the second camera may be disposed on the taping head, such that the robot arm can move the second camera to a position in which the plurality of tape pockets are within the field of view of the second camera. Alternatively, the second camera may be at a fixed position, independent of the taping head and robot arm. The distance between the second camera and the carrier tape may depend on the resolution, focal length, and field of view of the second camera, and space required for the taping head to place the plurality of devices into the plurality of tape pockets of the carrier tape. While step 225 shown is being performed after step 220, it should be understood that step 225 may also be performed before or simultaneously with step 220. Step 225 may also be performed for each drop cycle or after a preset number of drop cycles.

At step 235, the processor determines dimension and position information of each of the plurality of tape pockets of the carrier tape based on the one or more images of the plurality of tape pockets of the carrier tape received from the second camera. It should be understood that based on manufacturing tolerances, the dimension and position information of each of the plurality of tape pockets of the carrier tape may differ. Consequently, the solution space and boundaries of each of the plurality of tape pockets may differ.

At step 236, the processor determines the solution space and boundaries of the plurality of tape pockets of the carrier tape based on the dimension and position information of each of the plurality of tape pockets. For example, image segmentation may be used to identify the boundaries of the plurality of tape pockets, which can be used to determine the dimension and position information of each of the plurality of tape pockets. Other ways of determining the dimension and position information of the plurality of tape pockets are possible and may depend on the type of carrier tape being processed by the method 200. Accordingly, when determining the placement solution of the taping head, the processor may use the solution space and boundaries of the specific tape pockets that will be placed with the plurality of devices extracted by the taping head, thereby further improving accuracy of alignment of the taping head and avoiding misplacement errors.

In some embodiments, the taping head may comprise a plurality of vacuum pads. The plurality of vacuum pads may be configured to individually engage each of the plurality of devices based on vacuum pressure from a vacuum source. For example, step 210 may comprise controlling, with the processor, the vacuum source to apply vacuum pressure to the plurality of vacuum pads to extract the plurality of devices from the plurality of tray pockets of the component tray. Accordingly, the plurality of devices will remain engaged with the plurality of vacuum pads as the robot arm moves the taping head within the volume. Similarly, step 250 may comprise controlling, with the processor, the vacuum source to stop applying vacuum pressure to the plurality of vacuum pads to individually place the plurality of devices into the plurality of tape pockets of the carrier tape based on the corrective movement. Accordingly, the plurality of devices can be released from the taping head to be placed in the plurality of tape pockets of the carrier tape.

It should be understood that after the plurality of devices extracted by the taping head are placed into the plurality of tape pockets of the carrier tape at step 250, method 200 may further comprise advancing/jogging the carrier tape with one or more actuators or motors to move additional tape pockets to a position to be loaded, and steps 210 to 240 can be repeated to extract additional devices from the component tray and place the devices into the additional tape pockets of the carrier tape with the taping head.

With the method, feedback from the image of the plurality of devices captured by the first camera can be used to determine a placement solution for the taping head to place each of the plurality of devices into the plurality of tape pockets of the carrier tape, which avoids misalignment of the taping head and misplacement of the plurality of devices. Further feedback from the image of the plurality of tape pockets of the carrier tape captured by the second camera can be used with the image of the plurality of devices captured by first camera to determine the placement solution to improve placement. Accordingly, processing time may be reduced for improved yield.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a taping head configured to extract a plurality of devices from a plurality of tray pockets of a component tray;
a first camera configured to capture one or more images of the plurality of devices extracted by the taping head; and
a processor in electronic communication with the taping head and the first camera, wherein the processor is configured to:
determine size and orientation information of each of the plurality of devices extracted by the taping head based on the one or more images of the plurality of devices received from the first camera;
determine a placement solution of the taping head to position each of the plurality of devices into a plurality of tape pockets of a carrier tape based on the size and orientation information of each of the plurality of devices, wherein the placement solution comprises at least one corrective movement of the taping head and a drop sequence of placing each of the plurality of devices into the plurality of tape pockets of the carrier tape; and
control the taping head to place the plurality of devices into the plurality of tape pockets of the carrier tape according to the placement solution.

2. The system of claim 1, further comprising:
a second camera configured to capture one or more images of the plurality of tape pockets of the carrier tape;
wherein the processor is in electronic communication with the second camera and is further configured to:
determine dimension and position information of each of the plurality of tape pockets of the carrier tape based on the one or more images of the plurality of tape pockets of the carrier tape received from the second camera; and
determine a solution space and boundaries of the plurality of tape pockets of the carrier tape based on the dimension and position information of each of the plurality of tape pockets.

3. The system of claim 1, wherein the corrective movement comprises a translational adjustment and/or a rotational adjustment of the taping head relative to the plurality of tape pockets of the carrier tape.

4. The system of claim 1, wherein the processor is further configured to:
determine locations of a center point and four corners of each of the plurality of devices based on the size and orientation information of each of the plurality of devices;
compare the locations of the center point and four corners of each of the plurality of devices to a solution space and boundaries of each of the plurality of tape pockets of the carrier tape; and
determine the corrective movement of the taping head to position the locations of the center point and four corners of each of the plurality of devices within the solution space and boundaries of each of the plurality of tape pockets of the carrier tape.

5. The system of claim 4, wherein the processor is further configured to:
determine a translational adjustment of the corrective movement to adjust an x, y position of the taping head such that the locations of the center point of each of the plurality of devices are within the solution space of each of the plurality of tape pockets of the carrier tape; and
determine a rotational adjustment of the corrective movement to adjust an angle along a rotation axis of the taping head such that the locations of the four corners of each of the plurality of devices are within the boundaries of each of the plurality of tape pockets of the carrier tape.

6. The system of claim 4, wherein the plurality of devices comprises N devices, the drop sequence comprises 1 to N drops, and the processor is further configured to:
iteratively reduce the number of devices in a drop in the drop sequence when no single corrective movement of the taping head positions the locations of the center point and four corners of each of the plurality of devices within the solution space and boundaries of each of the plurality of tape pockets of the carrier tape;
determine a corrective movement of the taping head to position the locations of the center point and four corners of each grouping of the plurality of devices within the solution space and boundaries of each corresponding grouping of the plurality of tape pockets of the carrier tape;
define the drop sequence based on the number of groupings of the plurality of devices having a corresponding corrective movement; and
control the taping head to place each grouping of the plurality of devices into each corresponding grouping of the plurality of tape pockets of the carrier tape according to the corresponding corrective movement and the drop sequence.

7. The system of claim 1, wherein the taping head comprises a plurality of vacuum pads configured to individually engage each of the plurality of devices based on vacuum pressure from a vacuum source.

8. The system of claim 7, wherein the processor is in electronic communication with the vacuum source and is further configured to:
control the vacuum source to apply vacuum pressure to the plurality of vacuum pads to extract the plurality of devices from the plurality of tray pockets of the component tray; and
control vacuum source to stop applying vacuum pressure to the plurality of vacuum pads to individually place the plurality of devices into the plurality of tape pockets of the carrier tape.

9. The system of claim 1, wherein the processor is further configured to control the taping head to position the plurality of devices a preset distance from the first camera in order for the first camera to capture the one or more images of the plurality of devices extracted by the taping head.

10. The system of claim 1, wherein the plurality of devices are integrated circuits (ICs).

11. A method comprising:
extracting, with a taping head, a plurality of devices from a plurality of tray pockets of a component tray;
capturing, with a first camera, one or more images of the plurality of devices extracted by the taping head;
determining, with a processor, size and orientation information of each of the plurality of devices extracted by the taping head based on the one or more images received from the first camera;
determining, with the processor, a placement solution of the taping head to position the plurality of devices into a plurality of tape pockets of a carrier tape based on the size and orientation information of each of the plurality of devices, wherein the placement solution comprises at least one corrective movement of the taping head and a drop sequence of placing each of the plurality of devices into the plurality of tape pockets of the carrier tape; and
placing, with the taping head, the plurality of devices into the plurality of tape pockets of the carrier tape according to the placement solution.

12. The method of claim 11, further comprising:
capturing, with a second camera, one or more images of the plurality of tape pockets of the carrier tape;
determining, with the processor, dimension and position information of each of the plurality of tape pockets of the carrier tape based on the one or more images of the plurality of tape pockets of the carrier tape received from the second camera; and
determining, with the processor, a solution space and boundaries of the plurality of tape pockets of the carrier tape based on the dimension and position information of each of the plurality of tape pockets.

13. The method of claim 11, wherein the corrective movement comprises a translational adjustment and/or a rotational adjustment of the taping head relative to the plurality of tape pockets of the carrier tape.

14. The method of claim 11, wherein determining, with the processor, the placement solution of the taping head to position the plurality of devices into a plurality of tape pockets of a carrier tape based on the size and orientation information of each of the plurality of devices comprises:
determining, with the processor, locations of a center point and four corners of each of the plurality of devices based on the size and orientation information of each of the plurality of devices;
comparing, with the processor, the locations of the center point and four corners of each of the plurality of devices to a solution space and boundaries of each of the plurality of tape pockets of the carrier tape; and
determining, with the processor, the corrective movement of the taping head to position the locations of the center point and four corners of each of the plurality of devices within the solution space and boundaries of each of the plurality of tape pockets of the carrier tape.

15. The method of claim 14, wherein determining, with the processor, the corrective movement of the taping head to position the locations of the center point and four corners of each of the plurality of devices within the solution space and boundaries of each of the plurality of tape pockets of the carrier tape comprises:
determining, with the processor, a translational adjustment of the corrective movement to adjust an x, y position of the taping head such that the locations of the center point of each of the plurality of devices are within the solution space of each of the plurality of tape pockets of the carrier tape; and
determining, with the processor, a rotational adjustment of the corrective movement to adjust an angle along a rotation axis of the taping head such that the locations of the four corners of each of the plurality of devices are within the boundaries of each of the plurality of tape pockets of the carrier tape.

16. The method of claim 14, wherein the plurality of devices comprises N devices, the drop sequence comprises 1 to N drops, and determining, with the processor, the placement solution of the taping head to position the plurality of devices into a plurality of tape pockets of a carrier tape based on the size and orientation information of each of the plurality of devices further comprises:
iteratively reducing, with the processor, the number of devices in a drop in the drop sequence when no single corrective movement of the taping head positions the locations of the center point and four corners of each of the plurality of devices within the solution space and boundaries of each of the plurality of tape pockets of the carrier tape;
determining, with the processor, a corrective movement of the taping head to position the locations of the center point and four corners of each grouping of the plurality of devices within the solution space and boundaries of each corresponding grouping of the plurality of tape pockets of the carrier tape; and
defining, with the processor, the drop sequence based on a number of groupings of the plurality of devices having a corresponding corrective movement.

17. The method of claim 16, wherein placing, with the taping head, the plurality of devices into the plurality of tape pockets of the carrier tape based on the placement solution comprises:
placing, with the taping head, each grouping of the plurality of devices into each corresponding grouping of the plurality of tape pockets of the carrier tape according to the corresponding corrective movement and the drop sequence.

18. The method of claim 11, wherein the taping head comprises a plurality of vacuum pads configured to individually engage each of the plurality of devices using vacuum pressure from a vacuum source, and extracting, with the taping head, the plurality of devices from the plurality of tray pockets of the component tray comprises:
controlling, with the processor, the vacuum source to apply vacuum pressure to the plurality of vacuum pads to extract the plurality of devices from the plurality of tray pockets of the component tray.

19. The method of claim 18, wherein placing, with the taping head, the plurality of devices into the plurality of tape pockets of the carrier tape based on the placement solution comprises:
controlling, with the processor, the vacuum source to stop applying vacuum pressure to the plurality of vacuum pads to individually place the plurality of devices into the plurality of tape pockets of the carrier tape based on the corrective movement.

20. The method of claim 11, further comprising:
positioning, with the taping head, the plurality of devices at a preset distance from the first camera in order for the first camera to capture the one or more images of the plurality of devices extracted by the taping head.
